(19) United States
(12) Patent Application Publication
(10) Pub. No.: US 2025/0167006 A1
(43) Pub. Date: May 22, 2025

(54) GALLIUM OXIDE SUBSTRATE AND METHOD OF MANUFACTURING GALLIUM OXIDE SUBSTRATE

(71) Applicant: AGC Inc., Tokyo (JP)

(72) Inventor: Yusuke HIRABAYASHI, Tokyo (JP)

(73) Assignee: AGC Inc., Tokyo (JP)

(21) Appl. No.: 19/034,990

(22) Filed: Jan. 23, 2025

Related U.S. Application Data
(62) Division of application No. 17/493,082, filed on Oct. 4, 2021.
Application No. 17/493,082 is a continuation of application No. PCT/JP2020/011995, filed on Mar. 18, 2020.

(30) Foreign Application Priority Data
Apr. 8, 2019 (JP) 2019-073548

(51) Int. Cl. H01L 21/463; C01G 15/00; C30B 29/16; H10D 62/57; H10D 62/80

(52) U.S. Cl. CPC H01L 21/463; C01G 15/00; C30B 29/16; H10D 62/57; H10D 62/80

(57) ABSTRACT

A gallium oxide substrate includes first and second main surfaces. When measured data z₀(r,θ) of height differences of points (r,θ,z) on the first main surface from a least square plane of the first main surface are approximated by a function z(r,θ)=Σaₙₘzₙₘ(r,θ), a ratio of a first maximum height difference of a component of z(r,θ) obtained by summing terms aₙₘzₙₘ(r,θ) with an index j of 4, 9, 16, 25, 36, 49, 64, and 81, when the second main surface is placed facing a horizontal flat surface, to a diameter of the first main surface is 0.39×10⁻⁴ or less, and a ratio of a second maximum height difference of a component of z(r,θ) obtained by summing terms aₙₘzₙₘ(r,θ) with j of from 4 to 81, when an entire surface of the second main surface is adsorbed to a flat chuck surface, to the diameter is 0.59×10⁻⁴ or less.

### CROSS-REFERENCE TO RELATED APPLICATIONS

The present application is a divisional application of U.S. patent application Ser. No. 17/493,082, filed Oct. 4, 2021, which is a continuation application of International Application No. PCT/JP2020/011995, filed Mar. 18, 2020, which claims priority to Japanese Patent Application No. 2019-073548 filed Apr. 8, 2019. The contents of these applications are incorporated herein by reference in their entirety.

### BACKGROUND OF THE INVENTION

### 1. Field of the Invention

The present disclosure relates to gallium oxide substrates and methods of manufacturing gallium oxide substrates.

### 2. Description of the Related Art

Recently, compound semiconductor substrates have been used instead of silicon semiconductor substrates. Compound semiconductors include, for example, silicon carbide, gallium nitride, and gallium oxide. Compound semiconductors are excellent in large band gaps compared with silicon semiconductors. Compound semiconductor substrates are polished, and epitaxial films are formed on polished surfaces.

Japanese Unexamined Patent Application Publication No. 2016-13932 discloses a method of manufacturing a gallium oxide substrate. The method includes polishing only one side of the gallium oxide substrate using a slurry containing colloidal silica. The subject of Japanese Unexamined Patent Application Publication No. 2016-13932 is to improve a shaping property of the gallium oxide substrate in which the crystal system is a monoclinic system having poor symmetry and strong cleaving property.

### SUMMARY OF INVENTION

### Problem to be Solved by the Invention

Typically, a single-sided polishing device includes a lower surface plate, an upper surface plate, and a nozzle. The lower surface plate is arranged horizontally and a polishing pad is attached to an upper surface of the lower surface plate. The upper surface plate is arranged horizontally and the gallium oxide substrate is fixed to a lower surface of the upper surface plate. The gallium oxide substrate has a first main surface and a second main surface opposite to the first main surface. The upper surface plate holds the gallium oxide substrate horizontally and presses the first main surface of the gallium oxide substrate against the polishing pad. The lower surface plate is rotated around a rotational center line orthogonal to the lower surface plate. The upper surface plate rotates passively with the rotation of the lower surface plate. The nozzle supplies a polishing slurry from above to the polishing pad. The polishing slurry is supplied between the gallium oxide substrate and the polishing pad. The first main surface of the gallium oxide substrate is flatly polished with the polishing slurry. Because the second main surface of the gallium oxide substrate is fixed to the lower surface of the upper surface plate, irregularities of the lower surface of the upper surface plate are transferred to the second main surface.

Because the single-sided polishing device polishes only the first main surface, after the polishing, a residual stress of the first main surface is different from the residual stress of the second main surface. As a result, according to the Twyman effect the gallium oxide substrate may be warped. In addition, when the second main surface of the gallium oxide substrate is detached from the upper surface plate and an entire surface is adsorbed to a flat chuck surface, the first main surface is deformed in the same shape as that of the lower surface of the upper surface plate. Thus, the irregularities of the lower surface of the upper surface plate may appear on the first main surface.

Conventionally, flatness of gallium oxide substrates has been poor, and the transfer accuracy of exposure patterns to the gallium oxide substrates has been low.

An aspect of the present disclosure provides a technique that can improve a flatness of a gallium oxide substrate and can accurately transfer an exposure pattern to the gallium oxide substrate.

### Means for Solving Problems

According to an aspect of the present disclosure, a gallium oxide substrate includes a first main surface; and a second main surface which is opposite to the first main surface.

When measured data z₀(r, θ) of height differences of points (r, θ, z) on the first main surface from a reference plane, which is a least square plane of the first main surface, are approximated by a function z(r, θ) expressed by equation (1), j is an index presenting a combination of n and k, expressed by equation (4), aₙₘ is a coefficient obtained by equation (5), parameters (r, θ) are polar coordinates on the reference plane, n is an integer greater than or equal to 0 and less than or equal to k, k is 16, m is an even number within a range from −n to +n when n is an even number, and m is an odd number within a range from −n to +n when n is an odd number,
a ratio (PV1/D) of a first maximum height difference (PV1) of a component of z(r, θ) obtained by summing all terms aₙₘzₙₘ(r, θ) with j which are 4, 9, 16, 25, 36, 49, 64, and 81, when the second main surface is placed facing a horizontal flat surface, to a diameter (D) of the first main surface is less than or equal to 0.39×10⁻⁴, and
a ratio (PV2/D) of a second maximum height difference (PV2) of a component of z(r, θ) obtained by summing all terms aₙₘzₙₘ(r, θ) with j which are greater than or equal to 4 and less than or equal to 81, when an entire surface of the second main surface is adsorbed to a flat chuck surface, to the diameter (D) of the first main surface is less than or equal to 0.59×10⁻⁴.

$$\begin{matrix}[ Math . 1 ] & \\ z ( r , θ ) = {\sum }_{n = 0}^{k} {\sum }_{m = - n}^{n} {a}_{n m} {z}_{n m} ( r , θ ) & ( 1 )\end{matrix}$$

$$\begin{matrix}[ Math . 2 ] & \\ {z}_{n m} ( r , θ ) = \{ \begin{matrix}{R}_{n}^{m} ( r ) cos ( m θ ) & m \geq 0 \\ {R}_{n}^{m} ( r ) sin ( \vert m \vert θ ) & m < 0\end{matrix} & ( 2 )\end{matrix}$$

$$\begin{matrix}[ Math . 3 ] & \\ {R}_{n}^{m} ( r ) = \{ \begin{matrix}{{\sum }^{\frac{n - m}{2}}}_{i = 0} \frac{{( - 1 )}^{i} ( n - i ) !}{i ! ( \frac{n + m}{2} - i ) ! ( \frac{n - m}{2} - i ) !} {r}^{n - 2 i} & n - m is even \\ 0 & n - m is odd\end{matrix} & ( 3 )\end{matrix}$$

$$\begin{matrix}[ Math . 4 ] & \\ j = {( 1 + \frac{n + \vert m \vert}{2} )}^{2} - 2 \vert m \vert + ⌊ \frac{1 - sgn m}{2} ⌋ & ( 4 )\end{matrix}$$

$$\begin{matrix}[ Math . 5 ] & \\ {a}_{n m} = \frac{{\int }_{0}^{2 π} {\int }_{0}^{D / 2} {z}_{0} ( r , θ ) {z}_{n m} ( r , θ ) r dr d θ}{{\int }_{0}^{2 π} {\int }_{0}^{D / 2} {z}_{n m} ( r , θ ) {z}_{n m} ( r , θ ) r dr d θ} & ( 5 )\end{matrix}$$

### Effects of the Invention

According to the aspect of the present disclosure, a flatness of a gallium oxide substrate can be improved, and an exposure pattern can be transferred to the gallium oxide substrate with high accuracy.

### BRIEF DESCRIPTION OF DRAWINGS

Other objects and further features of the present disclosure will be apparent from the following detailed description when read in conjunction with the accompanying drawings, in which:

FIG. 1 is a flowchart illustrating a method of manufacturing a gallium oxide substrate according to an embodiment of the present disclosure;

FIG. 2 is a perspective view illustrating an example of a single-sided polishing device for performing the first stage single-sided polishing shown in FIG. 1;

FIG. 3 is a cross-sectional view illustrating the example of the single-sided polishing device for performing the first stage single-sided polishing in FIG. 1;

FIG. 4 is a perspective view illustrating an example of a double-sided polishing device for performing the double-sided polishing shown in FIG. 1;

FIG. 5 is a cross-sectional view illustrating the example of the double-sided polishing device for performing the double-sided polishing shown in FIG. 1;

FIG. 6 is a cross-sectional view illustrating an example of the gallium oxide substrate when a first maximum height difference (PV1) is measured;

FIG. 7 is a diagram showing zₙₘ(r, θ) for j=1 (n=0, m=0), j=2 (n=1, m=1), j=4 (n=2, m=0), and j=9 (n=4, m=0), respectively; and

FIG. 8 is a cross-sectional view illustrating an example of the gallium oxide substrate when a second maximum height difference (PV2) is measured.

### MODE FOR CARRYING OUT THE INVENTION

In the following, embodiments of the present disclosure will be described with reference to the drawings. In crystallographic descriptions in the specification of the present disclosure, individual orientations are indicated by [ ], collective orientations are indicated by < >, individual planes are indicated by ( ), and collective planes are indicated by { }. A negative crystallographic exponent is usually represented by a bar above a numeral, but in the specification of the present application the negative crystallographic exponent will be represented by a negative sign before the numeral.

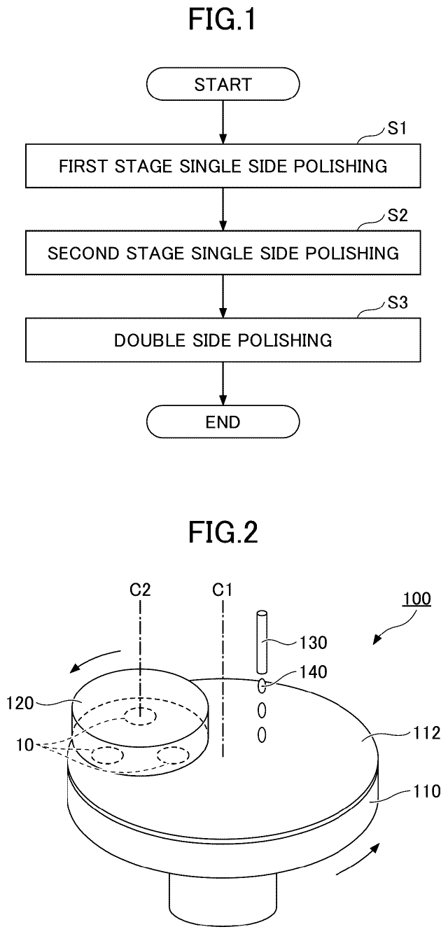

FIG. 1 is a flowchart illustrating a method of manufacturing a gallium oxide substrate according to an embodiment of the present disclosure. As shown in FIG. 1, the method of manufacturing the gallium oxide substrate includes a first stage single-sided polishing of the gallium oxide substrate (Step S1). For the gallium oxide substrate, for example, a β-Ga₂O₃ single crystal preliminarily sliced into a plate using a wire saw or the like and ground to a predetermined thickness using a grinding device or the like, is used. The gallium oxide substrate may include dopants or may not include dopants. Suitable dopants may include, for example, Si, Sn, Al or In.

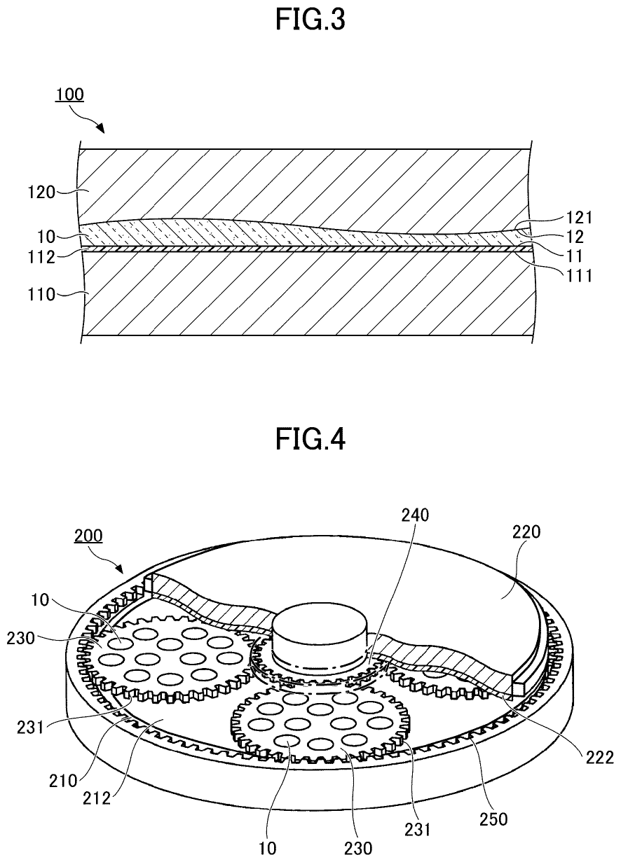

FIG. 2 is a perspective view illustrating an example of a single-sided polishing device for performing the first stage single-sided polishing shown in FIG. 1. FIG. 3 is a cross-sectional view illustrating the example of the single-sided polishing device for performing the first stage single-sided polishing shown in FIG. 1. In FIG. 3, irregularities of a lower surface 121 of an upper surface plate 120 are exaggerated. A single-sided polishing device for performing the second stage single-sided polishing (step S2) shown in FIG. 1 is the same as the single-sided polishing device 100 shown in FIG. 2 and FIG. 3, and is not shown.

The single-sided polishing device 100 includes a lower surface plate 110, the upper surface plate 120, and a nozzle 130. The lower surface plate 110 is arranged horizontally, and a lower polishing pad 112 is attached to an upper surface 111 of the lower surface plate 110. The upper surface plate 120 is arranged horizontally, and the gallium oxide substrate 10 is fixed to a lower surface 121 of the upper surface plate 120. The upper surface plate 120 holds the gallium oxide substrate 10 horizontally, and presses the gallium oxide substrate 10 against the lower polishing pad 112. The lower polishing pad 112 may be absent, in which case the upper surface plate 120 presses the gallium oxide substrate 10 against the lower surface plate 110. A diameter of the upper surface plate 120 is less than a radius of the lower surface plate 110, and the upper surface plate 120 is disposed radially outward of a rotational center line C1 of the lower surface plate 110. The rotational center line C2 of the upper surface plate 120 is parallel to the rotational center line C1 of the lower surface plate 110. The lower surface plate 110 is rotated around the center line C1. The upper surface plate 120 is rotated passively with the rotation of the lower surface plate 110. The upper surface plate 120 may be rotated independently of the lower surface plate 110, or may be rotated by a different motor.

The gallium oxide substrate 10 has a first main surface 11 with a circular shape and a second main surface 12 with a circular shape opposite to the first main surface 11. On an outer periphery of the gallium oxide substrate 10, a notch or the like which is not shown to indicate a crystal orientation of the gallium oxide is formed. An orientation flat may be formed instead of the notch. The first main surface 11 is, for example, a {001}plane. The {001}plane is a crystal plane perpendicular to the <001>direction, and may be either a (001) plane or a (00-1) plane.

In addition, the first main surface 11 may be a crystal plane other than the {001}plane. Moreover, the first main surface 11 may also have an off angle with respect to a predetermined crystal plane. The off angle improves crystallinity of an epitaxial film formed on the first main surface 11 after the polishing.

The nozzle 130 supplies a polishing slurry 140 to the lower polishing pad 112. The polishing slurry 140 includes, for example, particles and water. In this case, the particles are dispersoids and the water is a dispersion medium. The dispersion medium may be an organic solvent. The polishing slurry 140 is supplied between the gallium oxide substrate 10 and the lower polishing pad 112, and used for polishing the lower surface of the gallium oxide substrate 10 to be flat.

In the first stage single-sided polishing (step S1), for example, diamond particles are used for the particles. The Mohs hardness of diamond particles is 10. A median diameter D50 of the diamond particles is not particularly limited, and is, for example, 50 μm. The median diameter “D50” represents a 50% diameter in volume based cumulative fractions of a particle diameter distribution measured by a dynamic light scattering method. The dynamic light scattering method is a method for measuring particle diameter distribution by irradiating the polishing slurry 140 with laser light and observing scattered light with a photodetector.

In the first stage single-sided polishing (step S1), the first main surface 11 of the gallium oxide substrate 10 is pressed against the lower polishing pad 112 and polished to be flat by the lower polishing pad 112 and the polishing slurry 140. The second main surface 12 of the gallium oxide substrate 10 is fixed to the lower surface 121 of the upper surface plate 120, and irregularities of the lower surface 121 are transferred to the second main surface 12.

The upper surface 111 of the lower surface plate 110 also has irregularities in the same manner as the lower surface 121 of the upper surface plate 120, but the irregularities are unlikely to be transferred to the first main surface 11 of the gallium oxide substrate 10. Different from the upper surface plate 120, the lower surface plate 110 is displaced relative to the gallium oxide substrate 10.

As shown in FIG. 1, the method of manufacturing a gallium oxide substrate includes a second stage single-sided polishing of the gallium oxide substrate (step S2). In second stage single-sided polishing (step S2), in the same manner as the first stage single-sided polishing (step S1), the first main surface 11 of the gallium oxide substrate is pressed against the lower polishing pad 112, and polished to be flat by the lower polishing pad 112 and the polishing slurry 140.

In the second stage single-sided polishing (step S2), particles with a smaller median diameter D50 and lower Mohs hardness (i.e. softer) than those of the first stage single-sided polishing (step S1) may be used. For example, colloidal silica may be used for the particles. The second main surface 12 of the gallium oxide substrate 10 is fixed to the lower surface 121 of the upper surface plate 120, and the irregularities of the lower surface 121 are transferred to the second main surface 12.

As described above, the upper surface 111 of the lower surface plate 110 also has irregularities in the same manner as the lower surface 121 of the upper surface plate 120, but the irregularities are unlikely to be transferred to the first main surface 11 of the gallium oxide substrate 10. Different from the upper surface plate 120, the lower surface plate 110 is displaced relative to the gallium oxide substrate 10.

In the first stage single-sided polishing (step S1) and the second stage single-sided polishing (step S2), only one side (the first main surface 11) is polished. Then, a residual stress of the first main surface 11 after the polishing becomes different from a residual stress of the second main surface 12. As a result, the gallium oxide substrate 10 may be warped according to the Twyman effect. Moreover, when the second main surface 12 of the gallium oxide substrate 10 is detached from the upper surface plate 120, and the entire surface is adsorbed to a flat chuck surface, the first main surface 11 is deformed in the same shape as that of the lower surface 121 of the upper surface plate 120. Thus, the irregularities of the lower surface 121 of the upper surface plate 120 may appear on the first main surface 11.

Thus, as shown in FIG. 1, the method of manufacturing the gallium oxide substrate further includes polishing the gallium oxide substrate on both sides (step S3). Different from the first stage single-sided polishing (step S1) and the second stage single-sided polishing (step S2), the double-sided polishing (step S3) includes polishing the first main surface 11 and the second main surface 12 simultaneously.

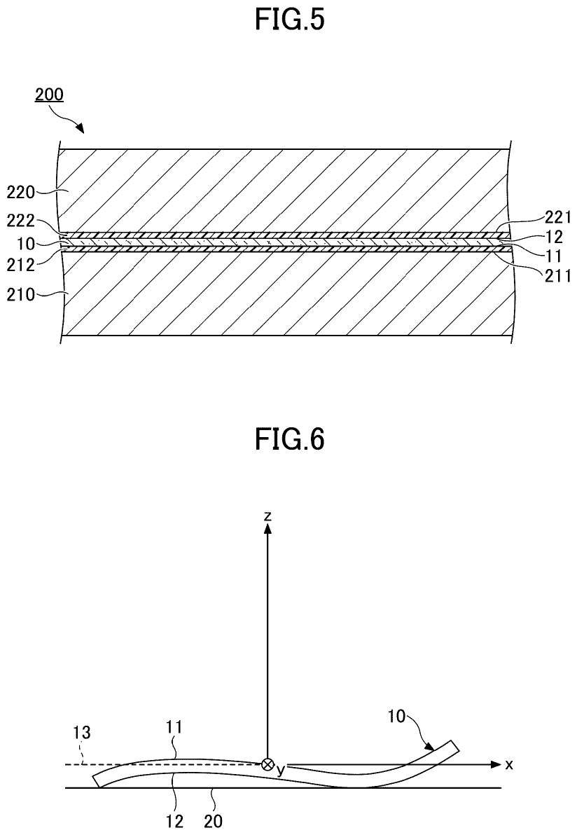

FIG. 4 is a perspective view illustrating an example of a double-sided polishing device for performing the double-sided polishing shown in FIG. 1. FIG. 5 is a cross-sectional view illustrating the example of the double-sided polishing device for performing the double-sided polishing shown in FIG. 1. The double-sided polishing device 200 includes a lower surface plate 210, an upper surface plate 220, a carrier 230, a sun gear 240, and an internal gear 250. The lower surface plate 210 is arranged horizontally and a lower polishing pad 212 is attached to an upper surface 211 of the lower surface plate 210. The upper surface plate 220 is arranged horizontally, and an upper polishing pad 222 is applied to a lower surface 221 of the upper surface plate 220. The carrier 230 holds the gallium oxide substrate 10 horizontally between the lower surface plate 210 and the upper surface plate 220. The carrier 230 is disposed radially outward of the sun gear 240 and radially inward of the internal gear 250. The sun gear 240 and the internal gear 250 are arranged concentrically and are engaged with an outer peripheral gear 231 of the carrier 230.

The double-sided polishing device 200 is, for example, a four-way double-sided polishing device in which the lower surface plate 210, the upper surface plate 220, the sun gear 240, and the internal gear 250 rotate about the same vertical rotational center line. The lower surface plate 210 and the upper surface plate 220 rotate in opposite directions to each other, and press the lower polishing pad 212 against the lower surface of the gallium oxide substrate 10 and press the upper polishing pad 222 against the upper surface of the gallium oxide substrate 10. At least one of the lower surface plate 210 and the upper surface plate 220 supply a polishing slurry to the gallium oxide substrate 10. The polishing slurry is supplied between the gallium oxide substrate 10 and the lower polishing pad 212, and used for polishing the lower surface of the gallium oxide substrate 10.

Moreover, the polishing slurry is also supplied between the gallium oxide substrate 10 and the upper polishing pad 222, and used for polishing the upper surface of the gallium oxide substrate 10.

For example, the lower surface plate 210, the sun gear 240, and the internal gear 250 rotate in the same direction in a top view. These rotation directions are opposite to the rotation direction of the upper surface plate 220. The carrier 230 revolves around the rotational center line while turning on its axis. The revolving direction of the carrier 230 is the same direction as the rotation direction of the sun gear 240 and the internal gear 250. The turning direction of the carrier 230 on its axis is determined by whether a product of a rotation speed and a pitch circle diameter of the sun gear 240 is greater than a product of a rotation speed and a pitch circle diameter of the internal gear 250. If the product of the rotation speed and the pitch circle diameter of the internal gear 250 is greater than the product of the rotation speed and the pitch circle diameter of the sun gear 240, the turning direction of the carrier 230 on its axis is the same direction as the revolving direction of the carrier 230 around the rotational center line. If the product of the rotation speed and the pitch circle diameter of the internal gear 250 is less than the product of the rotation speed and the pitch circle diameter of the sun gear 240, the turning direction of the carrier 230 on its axis is opposite to the revolving direction of the carrier 230 around the rotational center line.

The double-sided polishing device 200 may be a three-way double-sided polishing device or a two-way double-sided polishing device. The three-way double-sided polishing device may be any of, for example, (1) a double-sided polishing device in which the internal gear is fixed, and the lower surface plate 210, the upper surface plate 220, and the sun gear are rotated and (2) a double-sided polishing device in which the upper surface plate 220 is fixed, and the lower surface plate 210, the sun gear 240, and the internal gear 250 are rotated. Moreover, the two-way double-sided polishing device is, for example, a device in which the lower surface plate 210 and the upper surface plate 220 are fixed, and the sun gear 240 and the internal gear 250 are rotated.

The carrier 230 holds the gallium oxide substrate 10 horizontally, for example, with the first main surface 11 of the gallium oxide substrate facing down. The carrier 230 may hold the gallium oxide substrate 10 horizontally with the first main surface 11 of the gallium oxide substrate facing up. In either case, the first main surface 11 and the second main surface 12 of the gallium oxide substrate 10 are polished simultaneously.

Because in the double-sided polishing (step S3), different from the first stage single-sided polishing (step S1) and the second stage single-sided polishing (step S2), the first main surface 11 and the second main surface 12 are polished simultaneously, the difference between the residual stress of the first main surface 11 and the residual stress of the second main surface 12 after the polishing can be reduced. Thus, the warpage due to the Twyman effect can be reduced.

The warpage due to the Twyman effect will be assessed by using a first maximum height difference (PV1) which will be described later. FIG. 6 is a diagram depicting a side view of the gallium oxide substrate when the first maximum height difference (PV1) is measured. As shown in FIG. 6, when the first maximum height difference (PV1) is measured, the gallium oxide substrate is placed with the second main surface 12 facing a horizontal flat surface 20 so that the gallium oxide substrate 10 is not deformed. In FIG. 6, an xy-plane including an x-axis and a y-axis orthogonal to each other are a least square plane of the first main surface 11. The least square plane of the first main surface 11 is a plane obtained by approximating the first main surface 11 by the least squares method. Moreover, in FIG. 6, a z-axis orthogonal to the x-axis and the y-axis is set to pass through a center of the first main surface 11.

Measured data z₀(r, θ) of the height difference of the first main surface 11 from the least square plane of the first main surface 11, as a reference plane 13, are approximated by z(r, θ) of the following equation (1).

$$\begin{matrix}[ Math . 6 ] & \\ z ( r , θ ) = {\sum }_{n = 0}^{k} {\sum }_{m = - n}^{n} {a}_{n m} {z}_{n m} ( r , θ ) & ( 1 )\end{matrix}$$

$$\begin{matrix}[ Math . 7 ] & \\ {z}_{n m} ( r , θ ) = \{ \begin{matrix}{R}_{n}^{m} ( r ) cos ( m θ ) & m \geq 0 \\ {R}_{n}^{m} ( r ) sin ( \vert m \vert θ ) & m < 0\end{matrix} & ( 2 )\end{matrix}$$

$$\begin{matrix}[ Math . 8 ] & \\ {R}_{n}^{m} ( r ) = \{ \begin{matrix}{{\sum }^{\frac{n - m}{2}}}_{i = 0} \frac{{( - 1 )}^{i} ( n - i ) !}{i ! ( \frac{n + m}{2} - i ) ! ( \frac{n - m}{2} - i ) !} {r}^{n - 2 i} & n - m is even \\ 0 & n - m is odd\end{matrix} & ( 3 )\end{matrix}$$

$$\begin{matrix}[ Math . 9 ] & \\ j = {( 1 + \frac{n + \vert m \vert}{2} )}^{2} - 2 \vert m \vert + ⌊ \frac{1 - sgn m}{2} ⌋ & ( 4 )\end{matrix}$$

$$\begin{matrix}[ Math . 10 ] & \\ {a}_{n m} = \frac{{\int }_{0}^{2 π} {\int }_{0}^{D / 2} {z}_{0} ( r , θ ) {z}_{n m} ( r , θ ) r dr d θ}{{\int }_{0}^{2 π} {\int }_{0}^{D / 2} {z}_{n m} ( r , θ ) {z}_{n m} ( r , θ ) r dr d θ} & ( 5 )\end{matrix}$$

where in the equations (1) to (5), (r, θ) are polar coordinates on the reference plane 13, n is a natural number greater than or equal to 0 and less than or equal to k, k is 16, m is even numbers within a range from −n to +n when n is an even number, m is odd numbers within a range from −n to +n when n is an odd number, j is an index representing a combination of n and k, and aₙₘ is a coefficient. As shown in the equation (4), in the embodiment, the Fringe notation is used for expressing a combination of two indices n and m by a single index j. The equation (2) expresses a Zernike polynomial. Because the Zernike polynomials are orthogonal polynomials, the coefficients aₙₘ can be obtained by the equation (5).

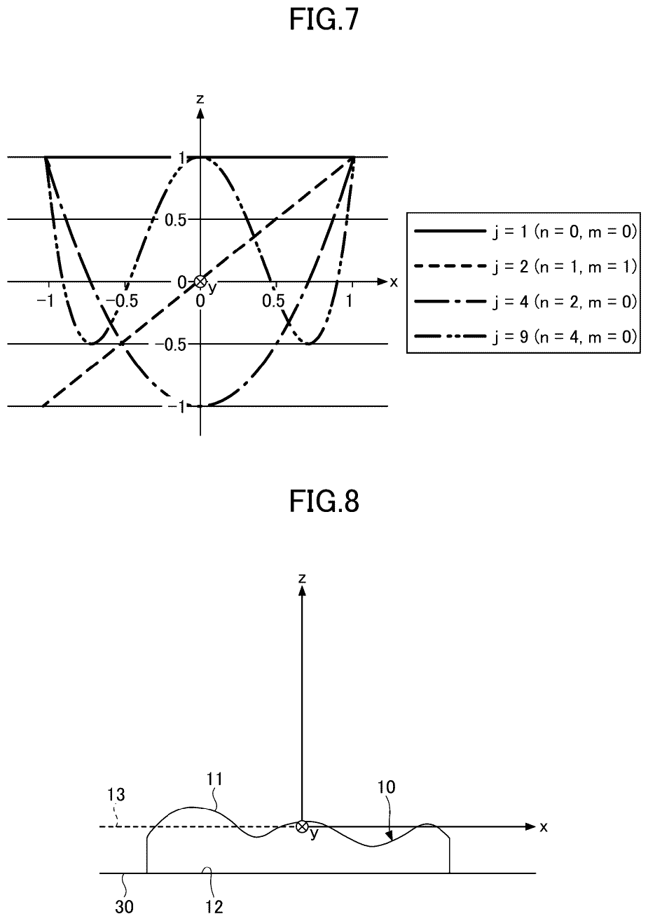

FIG. 7 is a diagram showing zₙₘ(r, θ) with j=1 (n=0, m=0), j=2 (n=1, m=1), j=4 (n=2, m=0), and j=9 (n=4, m=0), respectively.

As shown by a solid line in FIG. 7, zₙₘ(r, θ) with j=1 is an offset plane parallel to the xy-plane. The zₙₘ(r, θ) with j=1 is independent of r and 6.

As shown by a dashed line in FIG. 7, zₙₘ(r, θ) with j=2 is an inclined plane obtained by the xy-plane around the y-axis. Moreover, zₙₘ(r, θ) with j=3 (n=1, m=−1) is an inclined plane obtained by rotating the xy-plane around the x-axis.

As shown by a dotted chain line in FIG. 7, zₙₘ(r, θ) with j=4 is a curved surface obtained by rotating a quadratic curve on the xz-plane symmetric with respect to the z-axis by 180 degrees around the z-axis. The zₙₘ(r, θ) with j=4 depends on r, and is independent of 0.

As shown by a two-dot chain line in FIG. 7, zₙₘ(r, θ) with j=9 is a curved surface obtained by rotating a quartic curve on the xz-plane symmetric with respect to the z-axis by 180 degrees around the z-axis. The zₙₘ(r, θ) with j=9 depends on r, and is independent of 0.

When j is a square of a natural number (e.g. 4, 9, 16, 25, 36, 49, 64, 81, or the like), the zₙₘ (r, θ) depends on r, and is independent of 0. In addition, the zₙₘ(r, θ) with j=1 (n=0, m=0) is independent of either r or θ as described above.

The warpage due to the Twyman effect is caused by the difference between the residual stress of the first main surface 11 and the residual stress of the second main surface 12. The residual stress difference depends on r and is independent of 0.

Thus, the warpage due to the Twyman effect will be evaluated by the first maximum height difference (PV1) of the component of z(r, θ) obtained by summing all terms aₙₘzₙₘ(r, θ) with j which are 4, 9, 16, 25, 36, 49, 64, and 81. The first maximum height difference (PV1) is a height difference between the highest point with respect to the reference plane 13 and the lowest point with respect to the reference plane 13. The smaller the warpage due to the Twyman effect is, the smaller the first maximum height difference (PV1) is.

In addition, the terms aₙₘzₙₘ(r, θ) with j which is greater than 81 will be ignored because these terms have almost no effect on irregularities of the first main surface 11. Thus, the calculation becomes simpler.

In the double-sided polishing (step S3), different from the first stage single-sided polishing (step S1) and the second stage single-sided polishing (step S2), the first main surface 11 and the second main surface 12 are polished simultaneously, so that the warpage due to the Twyman effect can be reduced, as described above. As a result, a ratio (PV1/D) of the first maximum height difference (PV1) to the diameter (D) of the first main surface 11 is reduced to 0.39×10⁻⁴ or less. In addition, the first maximum height difference (PV1) can be reduced to 2 μm or less. In addition, the ratio PV1/D is a dimensionless quantity, and “10⁻⁴” in the value of the ratio PV1/D can be regarded to be equivalent to “μm/cm”.

The ratio PV1/D is, for example, less than or equal to 0.39×10⁻⁴ as described above. When the ratio PV1/D is less than or equal to 0.39×10⁻⁴, the warpage due to the Twyman effect can be reduced, so that the flatness of the gallium oxide substrate 10 can be improved, and consequently, an exposure pattern can be transferred to the gallium oxide substrate 10 with high accuracy. The ratio PV1/D is preferably 0.2×10⁻⁴ or less, and more preferably 0.1×10⁻⁴ or less. Moreover, the PV1/D is preferably 0.02×10⁻⁴ or more from a viewpoint of productivity.

The first maximum height difference PV1 is 2 μm or less, for example, as described above. When the first maximum height difference PV1 is 2 μm or less, the warpage due to the Twyman effect can be reduced, so that the flatness of the gallium oxide substrate 10 can be improved, and consequently, an exposure pattern can be transferred to the gallium oxide substrate 10 with high accuracy. The first maximum height difference PV1 is preferably 1 μm or less, and more preferably 0.5 μm or less. The first maximum height difference PV1 is preferably 0.1 μm or more from the viewpoint of productivity.

The diameter D of the first main surface 11 is not particularly limited, but is, for example, within a range from 5 cm to 31 cm, preferably within a range from 10 cm to 21 cm, and more preferably within a range from 12 cm to 15 cm.

In the double-sided polishing (step S3), different from the first stage single-sided polishing (step S1) and the second stage single-sided polishing (step S2), the lower surface plate 210 and the upper surface plate 220 are displaced relative to the gallium oxide substrate 10. As a result, transfer of the irregularities of the lower surface 221 of the upper surface plate 220 to the upper surface of the gallium oxide substrate 10 is suppressed, and the upper surface of the gallium oxide substrate 10 can be polished so as to be parallel to the lower surface of the gallium oxide substrate 10. Accordingly, when an entire surface of the second main surface 12 of the gallium oxide substrate 10 is adsorbed to a flat chuck surface 30, it is possible to prevent the irregularities of the lower surface 221 of the upper surface plate 220 from appearing on the first main surface 11.

The shape transfer of the upper surface plate 220 to the gallium oxide substrate 10 is evaluated by a second maximum height difference (PV2). FIG. 8 is a side view of the gallium oxide substrate when the second maximum height difference (PV2) is measured. As shown in FIG. 8, the second maximum height difference (PV2) is measured in a state where an entire surface of the second main surface 12 is adsorbed to the flat chuck surface 30. The adsorption is, for example, vacuum adsorption, and the chuck surface 30 is formed of a porous material. In FIG. 8, the xy-plane including the x-axis and the y-axis orthogonal to each other is the least square plane of the first main surface 11. Moreover, in FIG. 8, the z-axis orthogonal to the x-axis and the y-axis is set to pass through the center of the first main surface 11.

The measured data z₀(r, θ) of the height difference of the first main surface 11 from the reference plane 13, which is the least square plane of the first main surface 11, is approximated by z(r, θ) of the above-described equation (1). The zₙₘ(r, θ) of j=1, 2, and 3 represents flat planes as described above, and is not a relative component when measuring the second maximum height difference (PV2).

Thus, the shape transfer of the upper surface plate 220 to the gallium oxide substrate 10 is evaluated by the second maximum height difference (PV2) of the component of z(r, θ) obtained by adding all aₙₘzₙₘ(r, θ) with j which are greater than or equal to 4 and less than or equal to 81. The second maximum height difference (PV2) is a difference between the highest point with respect to the reference plane 13 and the lowest point with respect to the reference plane 13. The smaller the shape transfer of the upper surface plate 220 to the gallium oxide substrate 10 is, the smaller the second maximum height difference (PV2) is.

Note that the terms aₙₘzₙₘ(r, θ) with j which is greater than 81 do not contribute to the irregularities of the first main surface 11, and thus the terms will be neglected for simplicity.

In the double-sided polishing (step S3), different from the first stage single-sided polishing (step S1) and the second stage single-sided polishing (step S2), the first main surface 11 and the second main surface 12 are polished simultaneously, so that the shape transfer of the upper surface plate 220 to the gallium oxide substrate 10 can be suppressed, as described above. As a result, the ratio (PV2/D) of the second maximum height difference (PV2) to the diameter (D) of the first main surface 11 can be reduced to 0.59×10⁻⁴ or less. In addition, the second maximum height difference (PV2) can be reduced to 3 μm or less. In addition, the ratio PV2/D is a dimensionless quantity, and “10⁻⁴” in the value of the ratio PV2/D can be regarded to be equivalent to “μm/cm”.

The ratio PV2/D is, for example, less than 0.59×10⁻⁴, as described above. If the ratio PV2/D is less than or equal to 0.59×10⁻⁴, the shape transfer of the upper surface plate 220 to the gallium oxide substrate 10 can be suppressed. Thus, the flatness of the gallium oxide substrate 10 can be improved, and consequently, the exposure pattern can be transferred to the gallium oxide substrate 10 with high accuracy. The ratio PV2/D is preferably 0.2×10⁻⁴ or less, and more preferably 0.1×10⁻⁴ or less. Moreover, the ratio PV2/D is preferably 0.02×10⁻⁴ or more from the viewpoint of productivity.

The second maximum height difference PV2 is, for example, 3 μm or less, as described above. If the second maximum height difference PV2 is 3 μm or less, the shape transfer of the upper surface plate 220 to the gallium oxide substrate 10 can be suppressed, so that the flatness of the gallium oxide substrate 10 can be improved, and consequently, the exposure pattern can be transferred to the gallium oxide substrate 10 with high accuracy. The second maximum height difference PV2 is preferably 1 μm or less, and more preferably 0.5 μm or less. The second maximum height difference PV2 is preferably 0.1 μm or more from the viewpoint of productivity.

The double-sided polishing (step S3) includes polishing the first main surface 11 and the second main surface 12 of the gallium oxide substrate 10 simultaneously, in opposite directions to each other, with a polishing slurry containing particles having a Mohs hardness of 7 or less. If the Mohs hardness is 7 or less, the particles are soft, so that an occurrence of scratch on a surface of the gallium oxide substrate 10 can be suppressed, and cracking of the gallium oxide substrate 10 can be suppressed. The Mohs hardness is preferably 6 or less, and more preferably 5 or less. The Mohs hardness is preferably 2 or more from the viewpoint of the polishing speed.

For example, for the particle having a Mohs hardness of 7 or less, colloidal silica is used. The Mohs hardness of colloidal silica is 7. The material of the particles having the Mohs hardness of 7 or less is not limited to SiO₂. The material may be TiO₂, ZrO₂, Fe₂O₃, ZnO, or MnO₂. The Mohs hardness of TiO₂ is 6, the Mohs hardness of ZrO₂ is 6.5, the Mohs hardness of Fe₂O₃ is 6, the Mohs hardness of ZnO is 4.5, and the Mohs hardness of MnO₂ is 3. The polishing slurry used in the double-sided polishing (step S3) is required not to contain particles having the Mohs hardness greater than 7, and may contain two or more types of particles having the Mohs hardness of 7 or less.

In the double-sided polishing (step S3), the median diameter D50 of the particles contained in the polishing slurry is, for example, 1 μm or less. If the median diameter D50 is 1 μm or less, the particles are small, so that an excessive stress on the gallium oxide substrate 10 can be suppressed, and cracking of the gallium oxide substrate 10 can be suppressed. The median diameter D50 is preferably 0.7 μm or less, and more preferably 0.5 μm or less. The median diameter D50 is preferably 0.01 μm or more from the viewpoint of the polishing speed.

In the first half of the double-sided polishing (step S3), for example, polishing pressure is 9.8 kPa or less. In the first half of the double-sided polishing (step S3), since the first main surface 11 and the second main surface 12 are not sufficiently flat, the irregularities are large, and stress concentration easily occurs. When the polishing pressure is 9.8 kPa or less during a period of 50% or more of the first half of the double-sided polishing (step S3), an excessive stress on the gallium oxide substrate 10 is suppressed, and thereby cracking of the gallium oxide substrate 10 is suppressed. During the period of 50% or more of the first half of the double-sided polishing (step S3), the polishing pressure is preferably 8.8 kPa or less, and more preferably 7.8 kPa or less. In addition, from the viewpoint of the polishing speed, the polishing pressure is preferably 3 kPa or more during the period of 50% or more of the first half of the double-sided polishing (step S3).

During the entire period of the double-sided polishing (step S3), the polishing pressure may be constant. In the double-sided polishing (S3), the first main surface 11 and the second main surface 12 are gradually planarized, and the irregularities become gradually smaller. Therefore, the polishing pressure may be increased in order to improve the polishing speed.

The method of manufacturing the gallium oxide substrate is not limited to that shown in FIG. 1, and may be a method that includes the double-sided polishing (step S3). The method of manufacturing the gallium oxide substrate may include a process other than the processes shown in FIG. 1, for example, it may include a cleaning process of flushing off deposits (e.g. particles) of the gallium oxide substrate 10. The cleaning process is performed, for example, between the first stage single-sided polishing (step S1) and the second stage single-sided polishing (step S2) and between the second stage single-sided polishing (step S2) and the double-sided polishing (step S3).

### EXAMPLE

Hereinafter, examples and comparative examples will be described. Examples 1 to 3 are practical examples and Examples 4 to 7 are comparative examples.

### Examples 1 to 3

In Examples 1 to 3, the first stage single-sided polishing (step S1), the second stage single-sided polishing (step S2), and the double-sided polishing (step S3) were performed for a β-Ga₂O₃ single crystal substrate having a diameter of 50.8 mm and a thickness of 0.7 mm under the same condition as shown in FIG. 1.

In the first stage single-sided polishing (step S1), a (001) surface of the β-Ga₂O₃ single-crystal substrate was polished by the single-sided polishing device 100 shown in FIG. 2. A lower surface plate 110 made of tin and diamond particles having a particle diameter of 0.5 μm was used. In the first stage single-sided polishing (step S1), the substrate is pressed against the lower surface plate 110 and polished without using the lower polishing pad 112.

In the second stage single-sided polishing (step S2), the (001) surface of the β-Ga₂O₃ single-crystal substrate was polished by the single-sided polishing device 100 shown in FIG. 2. In the second stage single-sided polishing (step S2), different from the first stage single-sided polishing (step S1), the lower polishing pad 112 was used. In the second stage single-sided polishing (step S2), a lower polishing pad 112 made of polyurethane and colloidal silica particles having a particle diameter of 0.05 μm was used.

In the double-sided polishing (step S3), the (001) and (00-1) surfaces of the β-Ga₂O₃ single crystal substrate were simultaneously polished by the double-sided polishing device 200 shown in FIG. 4. For the double-sided polishing device 200, DSM9B by SpeedFam Co., Ltd. was used. For the lower polishing pad 212 and the upper polishing pad 222, N7512 by FILWEL Co., Ltd. was used. The polishing slurry contained 20% by mass of colloidal silica and 80% by mass of water. The median diameter D50 of the colloidal silica was 0.05 μm. During the entire period of the double-sided polishing (step S3), the polishing pressure was 9.8 kPa. The rotation speed of the lower surface plate 210 was 40 rpm, the rotation speed of the upper surface plate 220 was 14 rpm, the rotation speed of the sun gear 240 was 9 rpm, and the rotation speed of the internal gear 250 was 15 rpm. The pitch circle diameter of the sun gear 240 was 207.4 mm, and the pitch circle diameter of the internal gear 250 was 664.6 mm.

### Examples 4 to 6

In Examples 4 to 6, for a β-Ga₂O₃ single crystal substrate having a diameter of 50.8 mm and a thickness of 0.7 mm, only the first stage single-sided polishing (step S1) and the second stage single-sided polishing (step S2) were performed under the same condition as in Examples 1 to 3. That is, in Examples 4 to 6, the double-sided polishing (step S3) was not performed.

### Example 7

In Example 7, the first stage single-sided polishing (step S1), the second stage single-sided polishing (step S2), and the double-sided polishing (step S3) were performed under the same conditions as in Examples 1 to 3, except that diamond particles having a particle diameter of 0.5 μm were used as the double-sided polishing (step S3) particles, and except that an epoxy resin was used as the polishing pad for the diamond particles. As a result, the gallium oxide substrate 10 cracked during the double-sided polishing (step S3).

### [Result of Polishing]

The first maximum height difference (PV1) of the (001) plane, which is the first main surface 11, was measured in the state where the (00-1) plane, which is the second main surface 12, faces the horizontal flat surface 20 so as not to deform the gallium oxide substrate 10, as shown in FIG. 6. For the measuring device, PF-60 by Mitaka Kohki Co., Ltd. was used.

The second maximum height difference (PV2) of the (001) surface, which is the first main surface 11, was measured in a state where an entire surface of the (00-1) surface, which is the second main surface 12, is adsorbed to a flat chuck surface 30, as shown in FIG. 8. For the measured device, PF-60 by Mitaka Kohki Co., Ltd. was used.

The polishing results of Examples 1 to 6 are shown in TABLE 1. Result of Example 7 is not shown because the gallium oxide substrate 10 cracked during the double-sided polishing (step S3) as described above.

TABLE 1

| | | | Polish- | | | | |
|---|---|---|---|---|---|---|---|
| | | | ing | | | | |
| | Double- | | pres- | | | | |
| | sided | D50 | sure | PV1 | | PV2 | |
| | polishing | [μm] | [kPa] | [μm] | PV1/D | [μm] | PV2/D |
| Ex. 1 | Performed | 0.05 | 9.8 | 0.8 | 0.16 × 10⁻⁴ | 1.6 | 0.31 × 10⁻⁴ |
| Ex. 2 | Performed | 0.05 | 9.8 | 0.6 | 0.12 × 10⁻⁴ | 2.8 | 0.55 × 10⁻⁴ |
| Ex. 3 | Performed | 0.05 | 9.8 | 0.5 | 0.10 × 10⁻⁴ | 1.2 | 0.24 × 10⁻⁴ |
| Ex. 4 | Not | 0.05 | 9.8 | 3.6 | 0.71 × 10⁻⁴ | 4.7 | 0.93 × 10⁻⁴ |
| | performed | | | | | | |
| Ex. 5 | Not | 0.05 | 9.8 | 3.9 | 0.77 × 10⁻⁴ | 5.9 | 1.16 × 10⁻⁴ |
| | performed | | | | | | |
| Ex. 6 | Not | 0.05 | 9.8 | 4.5 | 0.89 × 10⁻⁴ | 5.2 | 1.02 × 10⁻⁴ |
| | performed | | | | | | |

As is obvious from TABLE 1, in Examples 1 to 3, different from Examples 4 to 6, the gallium oxide substrate 10 was subjected to the double-sided polishing (step S3), so that the ratio PV1/D was less than or equal to 0.39×10⁻⁴, and the first maximum height difference PV1 was 2 μm or less. The warpage due to the Twyman effect was found to be reduced by performing the double-sided polishing (step S3).

Moreover, as is obvious from TABLE 1, since in Examples 1 to 3, different from Examples 4 to 6, the gallium oxide substrate 10 was subjected to the double-sided polishing (step S3), the ratio PV2/D was less than or equal to 0.59×10⁻⁴, and the second maximum height difference PV2 was 3 μm or less. The shape transfer of the upper surface plate 220 to the gallium oxide substrate 10 was found to be suppressed by performing the double-sided polishing (step S3).

Furthermore, in Examples 1 to 3, since the Mohs hardness of the particles used in the double-sided polishing (step S3) was 7 or less, the median diameter D50 of the particles was 1 μm or less, and the polishing pressure was 9.8 kPa or less during the period of 50% or more of the first half of the double-sided polishing, the gallium oxide substrate did not crack during the double-sided polishing. On the other hand, in Example 7, since the Mohs hardness of the particles used in double-sided polishing (S3) exceeded 7, the gallium oxide substrate 10 cracked during the double-sided polishing.

In the first stage single-sided polishing (step S1), the diamond particles having the Mohs hardness of 10 were used for polishing, but the gallium oxide substrate 10 did not break. In the single-sided polishing, the gallium oxide substrate is unlikely to crack compared with the double-sided polishing. Thus, the single-sided polishing is considered to be employed in Japanese Unexamined Patent Application Publication No. 2016-13932.

As described above, preferred embodiments and practical examples of the present invention, with respect to a gallium oxide substrate and a method of manufacturing the gallium oxide substrate, have been described in detail. However, the present invention is not limited to the embodiment or the practical examples, but various variations, modification, replacements, additions, deletions and combinations may be made without departing from the scope recited in claims.

What is claimed is:

1. A method of manufacturing a gallium oxide substrate comprising:
double-side polishing of a first main surface and a second main surface of the gallium oxide substrate simultaneously in opposite directions to each other, with a polishing slurry containing particles having a Mohs hardness of 7 or less.

2. The method of claim 1, wherein
a 50% diameter in volume based cumulative fractions of a particle diameter distribution measured by a dynamic light scattering method of the particles contained in the polishing slurry is 1 μm or less.

3. The method of claim 1, wherein
a polishing pressure is 9.8 kPa or less during a period of 50% or more of a first half of a period of the double-side polishing of the first main surface and the second main surface.

4. The method of claim 1, wherein the first main surface is a {001}plane of the gallium oxide substrate.

5. The method of claim 1, wherein the first main surface has an off angle with respect to a {001}plane of the gallium oxide substrate.

6. The method of claim 1, further comprising first single-side polishing of the first main surface, without polishing the second main surface, and second single-side polishing of the second main surface, without polishing the first main surface, wherein the first single-side polishing second single-side polishing are performed prior to the double-side polishing.

7. The method of claim 6, further comprising slicing a gallium oxide single crystal to form the gallium oxide substrate, wherein said slicing is performed prior each of the first single-side polishing second single-side polishing.

8. The method of claim 6, wherein the second single-stage polishing is performed with particles with a smaller median diameter D50 and lower Mohs hardness than those of the first single-sided polishing.

9. The method of claim 6, wherein the first single-side polishing is performed prior to the second single-side polishing, the first single-side polishing is performed using diamond particles, the second single-side polishing is performed using silica particle.

10. The method of claim 1, wherein the particles of the polishing slurry are selected from the group consisting of TiO₂ particles, ZrO₂ particles, Fe₂O₃ particles, ZnO particles, and MnO₂ particles.
